(19) United States
(12) Patent Application Publication
(10) Pub. No.: US 2017/0001918 A1
(43) Pub. Date: Jan. 5, 2017

(54) Selective area coating sintering

(71) Applicant: nGimat Co., Norcross, GA (US)

(72) Inventors: Andrew Tye Hunt, Atlanta, GA (US); Stephen Johnson, Georgetown, KY (US)

(73) Assignee: nGimat Co., Norcross, GA (US)

(21) Appl. No.: 15/201,307

(22) Filed: Jul. 1, 2016

Related U.S. Application Data
(60) Provisional application No. 62/188,417, filed on Jul. 2, 2015.

(51) Int. Cl. C04B 37/02; H01J 37/32

(52) U.S. Cl. CPC C04B 37/021; H01J 37/32064; H01J 37/32522; H01J 2237/336; C04B 2235/666; C04B 2237/343; C04B 2237/348; C04B 2237/40

(57) ABSTRACT

The present disclosure is directed to a variable sintered coating or a variable microstructure coating as well as an apparatus and method of making such a variable coating onto substrates. The substrate has some electrical conductivity and is used as one electrode while an ionized gas is used as the other electrode that is moved over the areas of the powder coating to be sintered. An electrical current is used to cause a plasma produced through the gas, resulting in a combined energy and temperature profile sufficient for powder-powder and powder-substrate bonding. This preferred method is referred to as “flame-assisted flash sintering” (FAFS).

### CROSS REFERENCE TO RELATED CASES

This application claims the benefit of priority of U.S. Provisional Application Ser. No. 62/188,417, filed on Jul. 2, 2015. The entirety of that provisional application is hereby incorporated.

### STATEMENT REGARDING FEDERALLY SPONSORED RESEARCH OR DEVELOPMENT

This invention was made with government support under Contract No. F121-181-0680, awarded by the United States Air Force. The Government has certain rights in this invention.

### BACKGROUND

1. Field of the Disclosure

The present invention relates to an apparatus for and methods of sintering coatings and materials onto a surface or substrate. This can be achieved using processes including the use of flame-assisted flash sintering (FAFS), which involves a flame with an electric field plasma. The preferred method is capable of being used in an ambient atmospheric environment. By controlling the electrical voltage used to generate an electric plasma produced through the flame, and the path of the flame, the resulting defined energy profile is sufficient for powder-powder sintering and powder-substrate bonding in defined patterns in controlled areas. Material not in the high electric current fields can be removed after processing, leaving behind defined areas of sintered, bonded material. In another embodiment, the intensity of sintering can be varied over distances of microns, which is a finer scale than by previous techniques. Such controlled variation in grain structure has beneficial properties and uses.

2. Background of the Disclosure

Ceramic coatings on metallic substrates serve myriad purposes in a number of applications because the ceramics provide desirable wear, hardness, chemical, appearance, wetting, thermal, or electrical properties. Because ceramic materials generally have superior hardness with better temperature and corrosion resistance, compared with metals, ceramics can extend the life of heat exchangers operating in extreme environments, for example. Ceramics, though, are brittle and usually have different thermal expansion properties, which can lead to a sintered coating cracking.

Ceramic coatings are also essential to performance and longevity in thermal barrier coatings (TBC) for gas-turbine engines, among other applications. The hot gas streams in gas-turbine engines can reach temperatures well in excess of 1000° C. and a barrier coating is thus necessary to protect the underlying metal from corrosion and, for TBC, thermally insulating coatings are helpful.

Numerous other applications are known to benefit from ceramic coatings onto metals, including fuel cells, battery electrode coatings, wire-insulation coatings, wear and abrasion surfaces, cookware, engines, exhaust shields, power plants of various types, biomedical implants, surfaces exposed to supersonic gas flows, electronics, optics, and other applications.

Two common methods used to deposit thicker layers of ceramics onto metals are air plasma spraying (APS) and electron-beam physical vapor deposition (EB-PVD). In APS, ceramic powder is injected into an acetylene-oxygen flame nozzle that contains a plasma arc formed by a voltage and the high temperatures generated from the combustion process. As the powder feedstock is injected through this hot region (>2500° C.), the powder melts and some consolidates into large droplets that are then conveyed to the metal substrate where they splat-impact, cool, and resolidify. This method is used widely to make thick porous films of ceramics, but is not suitable for making small-scale features or films with controlled areas of high density and low porosity and other areas just microns away of high porosity and moderate or no sintering.

These porosity and smoothness issues are improved when using EB-PVD, where an intense beam of electrons melts and vaporizes a solid ceramic target inside a vacuum chamber. As a melt is formed, vapor-phase material is generated within the low-pressure chamber and a uniform coating is deposited on a nearby substrate. Although this process deposits films that are generally superior to APS, the method is costly, because it is slower and requires expensive vacuum chambers, source targets, and power supplies for beam generation and steering. Moreover, in any vapor-phase deposition, a large percentage of the target material becomes wasted and deposited on the surrounding chamber walls and because the process is line-of-sight, the substrate must be manipulated in the vacuum chamber to coat all the surfaces. Thus, cost is a limiting issue with EB-PVD and it is only used for the most demanding applications. Plasma-enhanced chemical vapor deposition (PECVD) is a similar technique in that it is a low-pressure vapor deposition process, but suffers from some of the same cost issues as EB-PVD, except that it is not as limited in line-of-sight. These vapor deposition processes deposit similarly over all exposed surfaces and do not provide for localized or small scale-microstructure control of the deposited material. There also is no sintering of material, as is the case with all vapor deposition processes, so there can be no selective area sintering.

Various techniques exist that use electric fields to sinter ceramic materials. Such techniques are collectively referred to as “field-assisted sintering” (FAST), and include spark plasma sintering (SPS), pulsed electric current sintering (PECS), and flash sintering. In all of these methods, an electric field is applied across a green body material and resistive heating caused by current flow consolidates the powder material. Traditional SPS applies uniaxial pressure to a ceramic green body sample that is sandwiched between two conductive graphite dies that generate the electric field. Commercial versions of such systems exist, but they are not well-suited to handling large-area coatings or complex shapes, and typically require a vacuum atmosphere. Published information shows such electric field-induced sintering has been applied to ceramic parts but not to coatings of ceramic on metals or other conductive substrates. They do not mention localized (small-scale) control of microstructure nor are the electrodes flexible and moveable, as is the case with the current innovation.

In a variation on SPS, several publications have demonstrated that so-called “flash sintering” can be used to consolidate ceramics at moderately low temperatures without the need for external pressure or a vacuum. Flash sintering uses an external heating source to bring the ambient temperature of the ceramic to a baseline temperature (for example, as low as ˜850-1000° C. for YSZ), and an electrical current flowing through the sample then consolidates the powder in a matter of seconds. Reduced sintering temperatures and times present a major opportunity for cost savings in materials processing. The actual temperature at which sintering occurs and the speed of sintering were shown to be controlled by the electric field strength. In each of the field-assisted processes above, the physical restriction of having two conductive electrodes limits the geometries of the ceramic parts being sintered. Because the electrodes are spaced apart and not moved, there is a lacking of any controlled sintering variation; indeed, any sintering variation is not well controlled and more of a random nature.

Although common applications of ceramic coating may be satisfied by the various ceramic coating processes described, there is a continuing need for a method of ceramic coating that produces very little waste in terms of coating material, that works well for large or contoured parts, and that can be applied under atmospheric conditions, free of the burdens of traditional vacuum chambers, can be processed at low temperatures, and which allows for the localized control of sintering or microstructures.

### SUMMARY OF THE INVENTION

The present invention comprises an apparatus and method capable of being used to make coatings with small-scale variations in sintering and microstructures onto substrates that have some electrical conductivity. The technique and apparatus for creating the sintered microstructures from powder coatings includes the use of a flame with an electric plasma to sinter the powder on to a substrate surface. The substrate is electrically conductive or semi-conductive and is used as one electrode while the flame is used as the other electrode that is moved over the areas of the powder coating to be sintered. An electrical voltage is used to generate an electric plasma within the flame, resulting in a combined temperature and energy profile sufficient for powder-powder sintering and powder-substrate bonding. This sintering method is referred to as “flame-assisted flash sintering” (FAFS). Because the flame's trajectory and motion, or that of the substrate, can be controlled via external motors, controllers, and the like, the area that is effectively sintered or morphologically changed can be very well controlled, with the sintered material areas can be just a micron or so away from non-consolidated materials. Another embodiment of the process modulates the electrical properties of the sinter arc plasma within the flame contact region to induce microscale variations in the sintering. Yet another embodiment to make microstructural variations across the smallest region of space involves setting the FAFS process parameters such that the plasma arc traces specific patterns within the flame zone, leaving only those areas where the arc contacted more intensely or fully sintered.

The FAFS process can sinter many materials on to a substrate surface through which milliamps of current can flow. Substrates can range from semiconductors, to carbon-based materials, to metals and slightly conductive ceramics. These can be pure materials, composites, or even just a conductive layer on another material that is conductive enough to allow for milliamps of current to flow when large potentials (˜100 to ˜5000 V) are applied. The substrate can be any shape or texture, but smoother surfaces and more uniform coatings provide for a more uniform sintering effect under consistent processing conditions.

Powders may include metals, semiconductors, ceramics, and composites. Suitable examples of metals include base metals and alloys, such as those listed in the ASTM database and other publications. Examples of semiconductors include those listed in various semiconductor databases and numerous publications, and include pure materials and mixed-valence materials. Suitable ceramics include metal oxides or metalloid oxides and most compounds in publications or ceramic phase-diagram databases. Composite examples include combinations of any of the metals, semiconductors, and/or ceramics above, such as stainless steel mixed with YSZ or alumina to better match thermal expansion coefficients or improve the bond strength to the substrate. Coatings may be composed of powders, binders, and coating-stabilizing additives, or can just be inorganics of the final desired coating composition. The binder may be an organic material, such as a polymer, that is volatilized before or during the FAFS process. Alternatively, the binder may be an inorganic material, such as a phosphate (e.g., alumina phosphate), or a metal organic that could be integrated into the ceramic structure, in part or whole, during the sintering process. Substrates may include metals, semiconductors, composites, conductor-coated insulators, and ceramics, so long as they conduct electricity better than the powder coating layer at sintering temperatures. Examples of suitable substrates include the semiconductors and metals above, with common ones including various grades and alloys of steel, titanium, aluminum, silver, precious metals, magnesium, silicon, carbonaceous materials, superalloys, and composites containing these.

The initial coatings may be deposited or formed onto the substrate by a variety of methods, including Meyer Rod drawing, doctor-blade coating, dip-coating, spin-coating, aerosol-jet printing, inkjet printing, electrophoretic deposition, and other processes. The FAFS process can then be run in the desired areas of the initial coating.

The present invention introduces a method to create a variably-sintered microstructure where the sintering variations are on a size scale smaller than any previous technique can achieve. Other advantages of the present invention when the variable sintering is realized through the FAFS process include that it enables a lower cost and non-contact method of electric field sintering of powder coatings, decreases sintering times, enables applications not suitable for vacuum chambers or furnaces, is amenable to large and complex shapes, and can control the degree of sintering and grain growth over small scales through judicious selection of process parameters. This includes going from hard sintered material to unconsolidated material, with any method of removing material, including rubbing with a plastic brush, that can clean the substrate of undesired material, resulting in a pattern or final coating area of sintered material.

### BRIEF DESCRIPTION OF THE DRAWINGS

FIG. 1 shows optical microscope images of a FAFS processed sample showing a design feature produced by not running over the whole area.

FIG. 1a shows a post FAFS-processed sample where the flame with a steady current was traversed in an offset raster pattern. This is before any attempt to remove loose material.

FIG. 1b shows the same area as taken from FIG. 1a, but after washing the surface in running water with a plastic bristle brush. One can see the fully removed areas and the unaffected FAFS-processed areas.

FIG. 1c shows the same area as taken from FIG. 1b but at a higher magnification to see better that there is a near-vertical step up of the coating in this example.

FIGS. 2a-c show optical microscope images of a post FAFS-processed surface where the current was turned up and down to form areas of high sintering and lower sintering.

FIGS. 3a-b show optical and scanning electron microscope images of variable sintered features at FAFS conditions where highly sintered material was formed in patterns within a single path width of the flame.

FIG. 4 shows a processed sample (alumina/YSZ composite #1) that was subjected to a stainless steel tip being dragged across the surface. The areas where the FAFS processing was executed actually abraded metal from the steel tip surface such that metal residue was left behind making five thin dark lines while in the four non-FAFS-processed powder areas, the metal tip readily digs into the powder and left no color trace.

FIGS. 5a-c show microscope images of a freestanding thick film of FAFS-processed alumina sintered powder, which was separated from the base aluminum metal substrate. All scale bars indicate 1 mm (1000 microns).

FIGS. 6a-e show schematic drawings of some theoretical temperature distributions during the FAFS process, which can vary greatly depending on operating conditions and materials.

### DETAILED DESCRIPTION OF THE INVENTION

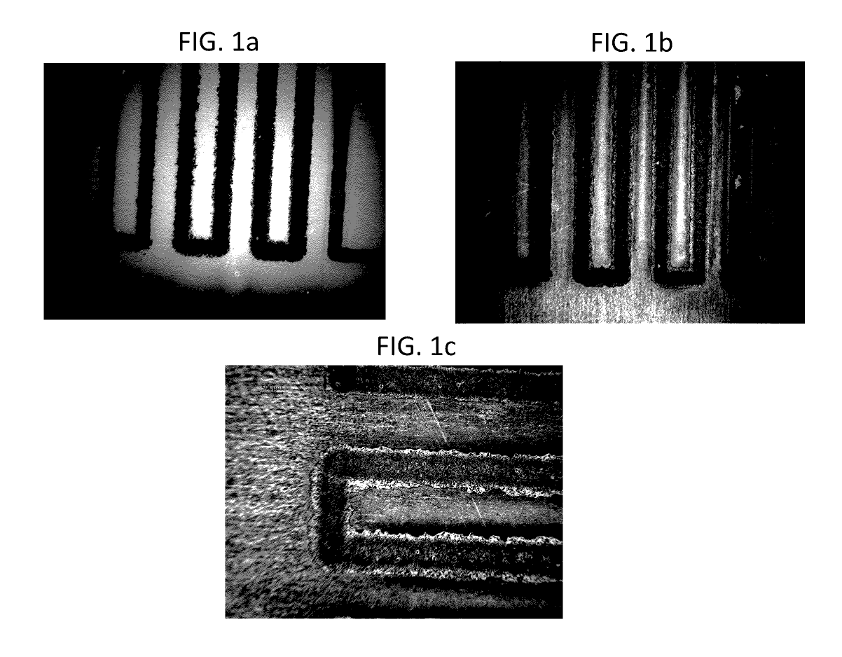

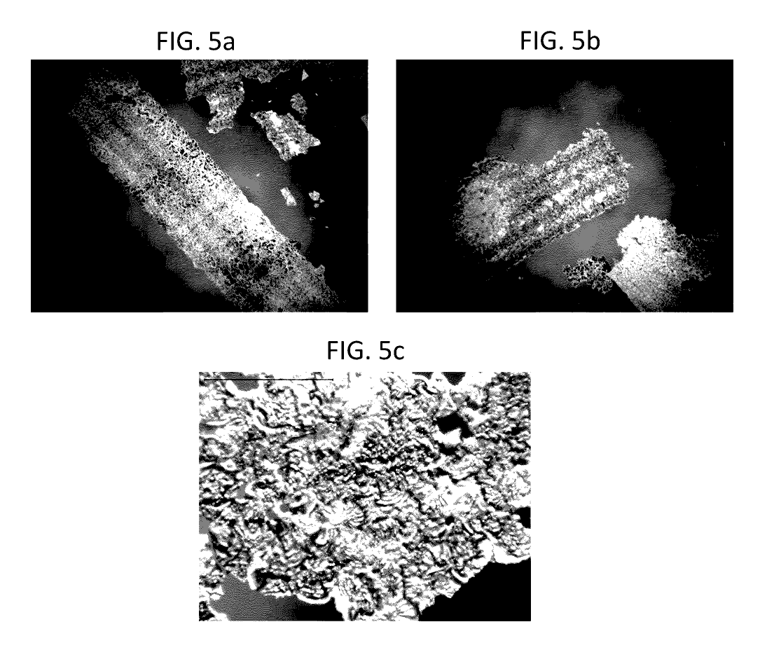

The images shown in FIGS. 1 to 5 illustrate key microstructure changes and patterning that are achievable. FIG. 1b is a detailed view, taken of the same area as FIG. 1a, showing features that remain after removal of unsintered material with a plastic bristle brush. Also shown in FIG. 1c is a higher magnification of the 1b area for clarity and the near vertical nature of the remaining edge of the coating. FIGS. 5a-c show that the patterned area can also be removed from the substrate in the form of a freestanding film. These are examples as to the significant variation in sintering achievable with little or no sintering basically adjacent to well-sintered material.

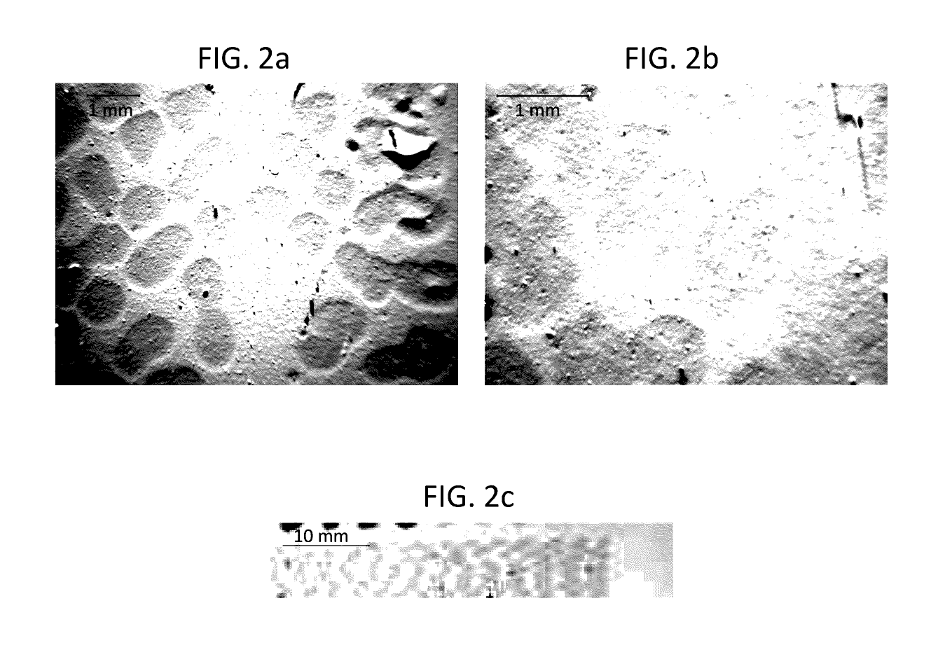

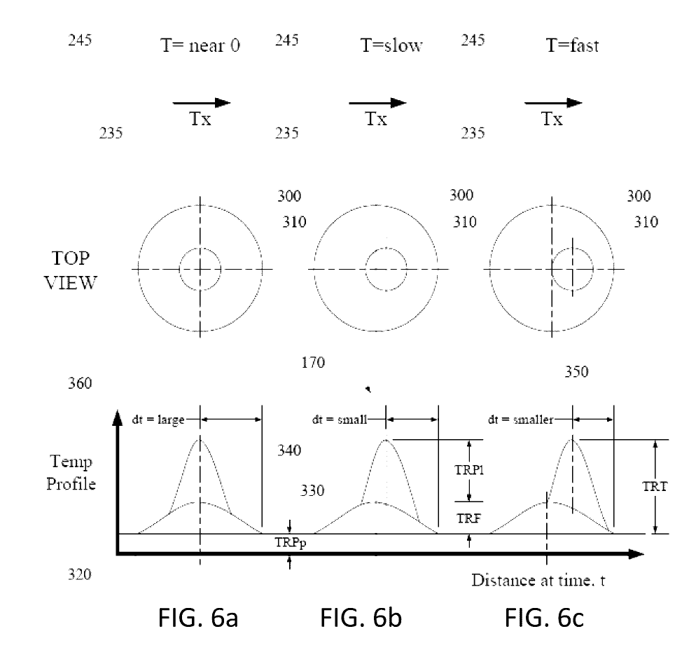

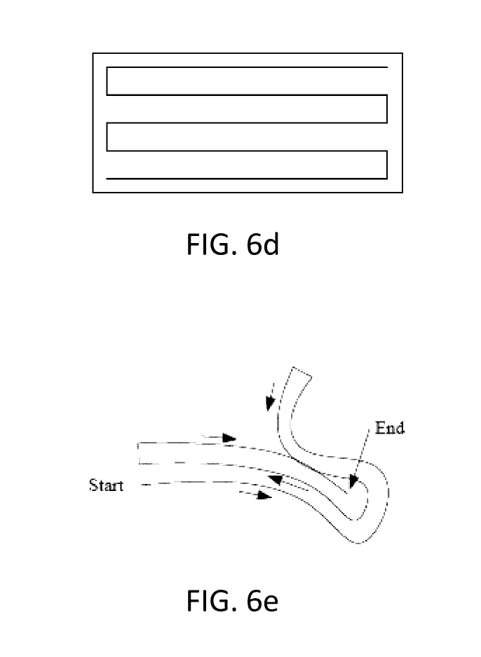

FIG. 2-5 are self explanatory along with the figure captions and are more fully explained in FIG. 6 and the examples.

FIGS. 6a-c describe the relationship of a combined flame and plasma heat/energy effects in combination with travel speed for a spot size on a substrate as measured at the substrate at a given point in time. These figures are just an example to help explain the processing factors which varies with materials, thicknesses and other conditions. Each figure shows a top view including a flame energy spot 300 and a plasma energy spot 310, with a plasma energy spot 310 having a smaller diameter than the flame energy spot 300. Each figure shows the relationship of the plasma energy spot 310 relative to the flame energy spot 300 based on traverse speed S 245 of the torch with a vector Tx 235. Just below, a relative temperature/energy profile of the substrate at a given position in time is illustrated, each of which corresponds to the top view. Note that the position of the plasma energy spot 310 is shown schematically as being roughly in the center of the flame energy spot 300 in the figures, but in some cases the plasma energy spot 310 may lead or trail the flame energy spot 300, depending on coating material, thickness, process parameters and conditions.

In FIG. 6a, the traverse speed S 245 is slower, resulting in the plasma energy spot 310 generally centered within the flame energy spot 300 in concentric circles. To simplify the following discussion, “temperature” is taken to mean energy available to perform the desired sintering and can be in various forms such as electrical current, plasma, thermal, or chemical sources. The corresponding total temperature rise TRT 360 includes a preheat temperature rise TRPp 345 from a preheat temperature profile 320, a flame temperature rise TRF 350 from a flame temperature profile 330, and a plasma temperature rise TRPl 355 from a plasma temperature profile 340. In these examples, a preheat temperature profile 320 exists. If not, the total temperature rise TRT 360 would likely be increased, because the consolidation temperature required for effective consolidation would remain unchanged. As the flame traverses, at least the first surface of substrate will experience a flame temperature rise TRF 350 from the flame energy spot 300, then a plasma temperature rise TRPl 355 from the plasma energy spot 310 after a period of time. The rate of temperature rise would be the temperature rise divided by time dt 370. For example, a rate of temperature rise would be (total temperature rise TRT 360/time dt 370).

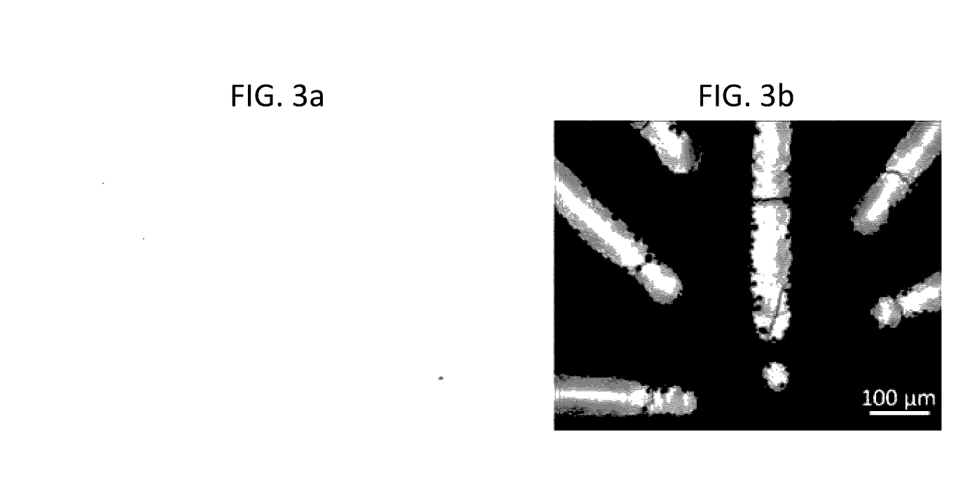

FIG. 6b shows a similar illustration to FIG. 6a but for a “moderate” traverse speed S 245, wherein the plasma energy spot 310 is shown offset from the flame energy spot 300 in a direction of travel of velocity Tx 235. In this case, the rate of total temperature rise TRT 360 would be greater than in FIG. 3a due to a decrease in the denominator, time dt 370, for close to the same numerator. Thus, at least the first surface of substrate will experience a more rapid temperature rise than in FIG. 6a.

FIG. 6c shows a case having a “fast” traverse speed S 245 (greater than “moderate”), wherein the plasma temperature rise TRPl 355 is experienced even more quickly due to a further decrease in time dt 370. A rate of total temperature rise that occurs too quickly may cause shock to the powder, substrate, or both. However, a rate of total temperature rise TRT 360 that is too slow may cause increased ceramic grain growth or oxidation of at least the first surface of substrate. Grain growth may be preferred in some applications, but it is generally desirable that oxidation of the substrate be minimized during surface bonding.

FIGS. 6d and 6e show different paths that a torch may traverse to consolidate an area of green powder onto a substrate. A rectangular pattern, as shown in FIG. 6d, may result in an ideal traverse path, having no overlaps. In contrast, FIG. 6e shows an irregular pattern having an area of overlap. At least a first surface of the substrate could experience a total temperature rise TTR 360 more than once in specific areas, depending on the controlled motion. Due to thermal cycling and differences in thermal expansion possibly causing cracking or spalling, it might be best to minimize overlaps. Additionally, the flame is not a rapid binary device that can be switched off then on again at will at very quick time intervals. An inventive solution includes varying the electric current or switching off the plasma but not the flame, reducing the total temperature rise TRT 360 of the surface to within acceptable limits for many applications. The electric current and its resulting plasma can be controlled very rapidly. If a further reduction of energy is needed the flame temperature may be altered by raising it or altering its fuel, gases, and their mixture; if raised, it results in an increased distance H, thereby further reducing the temperature of at least the first surface of substrate. These methods may also be used to preheat a region prior to sintering.

Although flame-assisted flash sintering is capable of being used in a vacuum environment, with flames being stable to at least 15 torr, it is practically preferred for use in non-vacuum environments, enabling in-place applications, such as very large components, repair applications, and applications requiring challenging orientations, such as vertical or overhead surface coatings.

The localized control of sintering of material can also occur with a plasma not formed by a flame. There are many traditional forms of plasma and some that produce local control of the plasma. TIG torches produce an electric arc at atmospheric pressure, and there are more uniform field plasmas that are formed at reduced pressures. Lasers can ionize gas and heat the surface some in a manner to replace a flame. An ionizable gas is generally used to produce these plasmas. While the preferred method of making the electric current for sintering is a flame, these other forms of plasmas that yield an electric current flow through gas can also be used. To help control the location of the current flow yielding the sintering, the surrounding gas should be less ionizable than the surrounding gas. The surrounding gas should be preferably at least ½ as ionizable, and more preferably at least 80% less ionizable. The voltage source should be close to or in the more ionizable gas flow, just as it should be for the flame when it is used to complete the electric circuit. Then, motion of the ionizable gas is relative to the substrate, and can be moved as desired to yield the areas of sintering wanted similar to when using the flame. A flame is an ionizable gas and is a form of chemically ionized gas, which makes the conduction of electricity easy. This makes the flame readily electrically ionizable. Ionizing gasses, without a flame, many sometimes require an initial high voltage or other energy form such as a laser to initiate the plasma.

Additionally, although FAFS was demonstrated for coating metals, it is applicable to any substrate having electrically even the smallest conductive properties. One only needs to pass milliamps of current through the substrate or a coating on the substrate with a high potential being applied.

Flame-assisted flash sintering may also be used for bonding or welding of material(s) to electron-passing surfaces. In this case, the material could be in a green, partially sintered, or fully sintered state. During bonding of the material, the material may also undergo partial or full sintering or grain growth. The material to be welded may be in the form of a green-state coating, as a tape or sheet, or a solid, shaped to conform to the substrate surface.

It is possible to sinter just desired areas with the FAFS process. If the material is in coating form, specific areas of the coating may be welded and sintered to the substrate by FAFS, and the unwelded and unsintered ceramic could be removed to expose the substrate in areas where no coating is desired. Unsintered material can be removed by many different processes, including washing, scrubbing, blowing, vibration, ultrasonic, and other known cleaning or removal methods. The FAFS process can be localized and it may be easier to define shapes and areas for the coating to remain than to mask or otherwise limit where the material is to be applied to the substrate.

It is also possible to run the selective sintering process such that the surface is sintered but the bonding to the substrate is weak, so that a sintered free standing sheet is created, as shown in FIG. 5. When subjected to force, such as thermal expansion strain, the sintered layer can delaminate, forming very thin sheets of ceramic. Thus, the selective sintering can be both horizontally and/or vertically controlled. Another example of desired vertical control would be a denser surface to provide protection but a more porous (less sintered but still adherent) under a layer to have other properties such as strain tolerance or thermal insulation.

For the examples described, the following preparations were made. A slurry was made for coating metal substrates. The slurry or paste can be made in many ways, or purchased. The following is simply the method used and does not limit the FAFS process.

Oxide powder was added to a solvent and dispersed with an ultrasonic probe (e.g., Hielscher UIP100hd). Slurries were sonicated for ˜10 min at ˜75% amplitude while manually stirred in an ice bath to minimize solvent evaporation. Slurries were cooled to room temperature via the ice bath prior to use. Slurries have also been made by rolling with grinding media and rapid rotation mixing methods, but almost any mixing technique that makes a stable slurry, dispersion, or ink can be used. The end fractional amounts are approximate because some solvent is lost.

### Example Slurry Recipes:

### YSZ

44.3 g Tosoh TZ-8YS YSZ powder
56.7 g n-butanol solvent/dispersant

### Alumina

35-40 g n-butanol solvent/dispersant
25 g of Baikalox BMA-15 Alumina powder
0.3-0.8 g Timcal SuperC65 Carbon Black powder

### Alumina/YSZ Composite #1

28.3 g n-butanol solvent/dispersant
20.5 g Tosoh TZ3YS20A YSZ/Alumina powder
0.3 g Timcal SuperC65 Carbon Black powder
0.5 g polyvinylpyrrolidone binder

### Alumina/YSZ Composite #2

8.8 g n-butanol solvent/dispersant
6.7 g Tosoh TZ-8YS YSZ powder+0.2 g Baikalox BMA-15 Alumina powder

The metal substrate was prepared as follows. After cutting to size and removal of masking adhesive, 0.075″ or 0.125″ thick substrates were cleaned with distilled ethanol in an ultrasonic bath cleaner for ˜15 min to remove any residual adhesive remaining on the substrate surface. After cleaning, substrates were rinsed in reverse osmosis or distilled water and sprayed dry with compressed air.

The slurry was applied as a coating onto the metal substrate as follows. Clean substrates were placed onto flattened sheets of aluminum foil and then onto the glass coating plate of a bench-top automated coating system. A wound-wire Meyer rod was cleaned by bath sonication in distilled ethanol and sprayed dry with compressed air. Cleaning cycles with ethanol were continued until the rod was completely clear of debris. With both the substrate and coating rod cleaned, the rod was inserted into the holder and lowered onto the substrate. Slurry was pipetted onto the substrate and the coating rod was drawn across. After coating, wet samples were transferred to a hot plate and dried for ˜5 min at ˜80-130° C. Once dry, coated substrates were inspected manually for defects and any excess coating was removed from the substrate back with a dust-free wipe.

Typical coating thicknesses for examples of alumina and YSZ/alumina composite samples were ˜12-15 μm, while YSZ samples typically had a dried thickness of ˜25-30 μm. A wide range of thicknesses have been processed. For the listed examples, the following equipment items were used when needed, but these items could be replaced with other equipment or set of components that perform similar functions:
1. The flame equipment used was a custom-built torch assembly consisting of a central flame (such as that produced by a Smith Little Torch with #5 tip) surrounded by a more diffuse annular flame. The latter flame is referred to as an “auxiliary flame” source because its primary purpose is to broaden the heat distribution and not to sinter the coating or deliver the plasma arc. The central flame torch typically protrudes from the auxiliary flame burner by ˜2 mm No second flame is needed for FAFS processing, but it can be helpful.
2. The voltage or current supplies used were a Stanford PS300 high voltage power supply, an Acopian P01HP60 high voltage power supply, and a Hoefer PS2500 high voltage power supply; they were used interchangeably and others can be used.
3. Alicat mass flow controllers, 0.5 SLPM and 2.0 SLPM (propane and O₂, respectively), as well as manual rotometers.
4. Omega OMEGALUX® infrared radiant panel heater (when needed).
5. Standard (industrial)-grade propane, methane, air, and oxygen gases.
6. A custom-made substrate chuck, made from type 309 stainless steel of dimensions 3″×6″×¼″. Any holder can be used but the substrate must be connected to the electrical circuit.

Using the equipment and materials prepared above, the examples listed below were made with the following process. Single-sided coated substrates were placed onto substrate chuck without clamping. The chuck was connected to electrical ground through a 100 kΩ ballast resistor, and was positioned atop the substrate heater such that the chuck rested only on the ceramic surface of the heater and did not physically touch the metallic body of the heater. Electrical grounding issues may occur if the metallic chuck does touch the metallic heater body, which is in electrical contact with essentially all components of the FAFS system (enclosure, motor drives, etc.). The ballast resistor was connected in series with the negative side of the power supply and served to restrict the maximum current in the circuit. The ballast resistor was intentionally placed on the negative side of the circuit so that the positive voltage applied to the torch was not attenuated through additional resistance before any plasma was ignited. Note that the ballast resistor must be of a sufficient wattage rating to handle the power delivered to it: in these experiments, a 25-W ballast resistor of 100-150 kΩ resistance was used. The resistor was found to help stabilize the power flow, but other means to finely control the electrical power, such as different circuitry or power supplies, can replace this or alter its value. We have successfully used over 90% lower resistances with stable FAFS processing.

The substrate heater was driven by a PID temperature controller and set to a temperature between 0° C. up to 800° C. In some cases, it was not necessary to use the substrate heater at all. This can be advantageous when one wishes not to heat the substrate material beyond the point of oxidation. It may even be best to cool the substrate.

The torch was clamped by an electrically insulating fixture onto a two-axis linear motion stage above, in the vicinity of the substrate heater and coated substrate. It is important that the torch be clamped using electrically insulating materials to prevent high voltage from being transferred to the motion system and thus the rest of the assembly. This is important both for operator safety and practical purposes, to avoid shorting the power supply to ground. The high voltage was supplied to the torch by means of an electrical spade lug that was silver-soldered to the body of the electrically conductive torch tip. A matching spade connector crimped onto the end of a cable (capable of withstanding high voltages) mates to the lug; this cable was connected to the positive terminal of the power supply.

A motion trajectory for the torch is determined and programmed into software that controls the motion of the entire three-axis system. It is useful to define a three-axis Cartesian coordinate system consisting of x, y, and z axes, such that the z-axis is parallel to the common understanding of vertical (up and down) movement, and the x-y plane is orthogonal to the z-axis. The trajectory used in all experiments to date consisted of holding the torch at a fixed height (z position) above the substrate surface while rastering along at a fixed speed in the x-y plane. At the end of each raster line (assuming rastering along the major axis, x), the substrate position is indexed in y and the torch returns to the initial x position. This pattern is repeated a number of times until the desired number of scan lines have been executed. Practical values used in our example experiments are shown in the table below, but wider ranges function. A robotic system can also be used.

| | | |
|---|---|---|
| z height | 2.0-5.0 | mm |
| z trajectory speed | 100-200 | mm/min |
| x trajectory speed | 50-200 | mm/min |
| y trajectory speed | 50-200 | mm/min |
| x scan length | 25-75 | mm |
| y index position length | 0.5-2.0 | mm |

Before electrically energizing the circuit, combustible gases are delivered to the torch and the flame is lit. Successful methods of gas delivery in these experiments included manual rotometer flow devices as well as electronic mass flow controllers designed to deliver precise amounts of gas. The latter has the advantage of creating a very stable flame, which is preferred to support a stable plasma. Fuel and oxidizing gases were delivered through separate mass flow controllers or rotometers and premixed within the torch assembly. Propane and oxygen were used as the primary fuel gases in these experiments. Methane was also tested as an acceptable fuel gas, but not in any of the incorporated examples. Air, oxygen, and argon mixed with oxygen, were demonstrated to be functional with the FAFS process. Various gases (or other fuel gases, such as butane and hydrogen) may be used once appropriate experimental conditions are ascertained.

By setting a voltage on the power supply, the FAFS circuit was energized. All experiments to date were performed as described above with the torch at a positive electrical potential with respect to the substrate chuck, and, by extension, the substrate. It may be that reversing the polarity of this voltage may show comparable or even greater success than the present configuration Changing the placement of the ballast resistor to the positive side of the circuit is also a modification that may be contemplated within the experimental parameters. It is noted that the torch is only electrically energized after lighting the combustible gases for safety reasons.

Voltages between 500 and 2000 V were applied to the torch (with respect to the substrate) to achieve currents ranging from 1 to 15 mA for the examples, but currents of 200 mA have been used and higher values are possible. The power supply may be controlled in constant current or constant voltage mode, as outlined in the proceeding examples. In theory, constant current mode should be preferable because the temperature increase due to the electrical current within the ceramic is proportional to power, and power is proportional to the square of the current multiplied by the ceramic resistance. As the ceramic resistance remains mostly constant, a change in current has a significant effect on the deposited power, and thus the temperature increase, within the ceramic. Variable sintering can also be obtained by purposefully adjusting current or voltage while processing, in which case non-constant electric potentials or currents are not just desired but purposefully created.

Once the flame is lit and the torch is electrically energized, the scanning motion trajectory begins, with the torch descending in the z-axis until it reaches the fixed height at which it will begin the x-y scanning motion. As the torch descends, it is sometimes necessary to also execute some x-y scanning motion so that a single point on the substrate does not get too hot. A typical value for this height is 2.5 mm, which provides enough space for stable combustion of the fuel-gas mixture before the primary combustion zone contacts the substrate surface. The z-height is an important parameter in the FAFS process, because the hottest section of the flame can reach temperatures in excess of 2,000° C., under certain combustion conditions, sufficient to oxidize, damage, or melt the surface of the ceramic coating or metal substrate. For this specific flame, use at a height of <1 mm may damage the coating due to erosion or extreme heat stress, while a height of >5 mm may be too far away from the surface to generate a stable plasma arc using the current torch apparatus. Other flames and torches will require different surface offsets, which can be determined by experimentation.

The nature of the FAFS process differs substantially between the two ceramic materials most studied and successfully demonstrated in this application, YSZ and alumina. In the case of YSZ, an extremely bright plasma was ignited as the torch approached a height of 3.8 mm Using a voltage of 850 V in constant voltage mode, the current generated was 2.5-13 mA. The substrate heater was set up to 1000° C. for 8YSZ but the substrate was not glowing red, so was much cooler than this. For YSZ conditions tried low temperatures tended to cause coating spalling or delamination. The plasma arc, which extended visibly from the torch tip to the substrate, moved rapidly and sporadically within the lateral extent of the combustion zone. For a x-y scanning speed of 25.4 mm/min, the 0.1-0.2 mm diameter plasma arc moved in such a way as to expose 50-80% of the ceramic coating within the lateral extent of the combustion zone.

Alumina with some carbon added, on the other hand, processed better when the substrate was not heated and the sample was at ambient temperature prior to processing. Using a current set point of 15 mA in constant current mode, the voltage obtained was of the order of 2,000 V. The nature of the plasma arc was fundamentally different than that of the 8YSZ case; luminescence was much less and a “shower” of multiple current arcs appeared rather than a single one. A high-frequency audible “hissing” sound was also typically heard in this case.

Once the scanning trajectory was complete, samples were either allowed to cool slowly to room temperature while residing on the substrate heater, or were instantly removed for examination. There was no noticeable difference observed between the two different cooling rates, although one may be preferable to the other upon closer examination in the future.

### Example 1

TABLE 1
Experimental parameters for Example 1.

| | | | | Flame + | |
|---|---|---|---|---|---|
| Heater | | | Traverse | ceramic | Flame + ceramic |
| SP | Voltage | Current | speed | resistance | electrical |
| (° C.) | (V) | (mA) | (mm/min) | (KΩ) | power (W) |
| N/A | 1500 | 8.0 | 50 | 50-100 | 3.2-6.4 |
| Nozzle | Auxiliary | | | | |
| height | nozzle | Propane | | Powder | Flame + plasma |
| H | height | flow | O₂ flow | size | arc diameter |
| (mm) | (mm) | (sccm) | (sccm) | (nm) | (mm) |
| 4.5 | 5.5 | 175 | 390 | 150 | 0.8-1.0 |

FIG. 1 shows images of actual test results from the experimental parameters and conditions shown in Table 1. The coating was alumina with carbon added. In this case, the electric plasma generally followed near the back edge of the intersection of the inner flame contact with the coating surface. When the width of the inner flame contact area was increased (by changing the flame or the flame height), the width of the electric arc processing and the resulting sintering could also be changed.

FIG. 1a shows the sample as-processed. The processing lines are visible. FIG. 1b shows the same sample after rinsing with water and brushing loose powder from the surface with a plastic brush. The processed lines resisted the brush and remained adhered to the surface, a testament to their bonding to the metal substrate. FIG. 1c shows a higher magnification view of the same sample.

### Example 2

In this example, the voltage was manually pulsed on and off to induce a variation in sintering across the sample surface. This modulation can engineer strain relief into the coating to avoid spallation, and can be done to selectively sinter for other benefits or selective removal processing. An appropriate analogy is designing cracks in concrete slabs to prevent the concrete from cracking as it expands and contracts. The coating is the alumina/YSZ composite #2, described above. The frequency of switching the voltage off and on was approximately 1 Hz. The frequency and speed can be adjusted to create the optimal pattern. The power supply was operated in constant-voltage mode. When the same FAFS process conditions were used without the pulsing, the coating would crack or spall in many areas.

Varying the current and voltage have another benefit in ending spot arcing. Spot arcing occurs when a low resistance spot is present through the coating and the arc stays located there for an extended time, with the arc stretching beyond the inner flame or ionizing gas stream, which excessively processes this spot and ends up underprocessing nearby coating. By effectively shutting off the arc and reestablishing it, the new point will be very close to the ionizing gas stream or flame.

TABLE 2
Experimental Parameters for Example 2

| | | | | Flame + | |
|---|---|---|---|---|---|
| Heater | | | Traverse | ceramic | Flame + ceramic |
| SP | Voltage | Current | speed | resistance | electrical |
| (° C.) | (V) | (mA) | (mm/min) | (KΩ) | power (W) |
| 950 | 1700 | 11.5 | 200 | 48 | 6.3 |
| Nozzle | Auxiliary | | | | |
| height | nozzle | Propane | | Powder | Flame + plasma |
| H | height | flow | O₂ flow | size | arc diameter |
| (mm) | (mm) | (sccm) | (sccm) | (nm) | (mm) |
| 2.5 | 3.5 | 80 | 390 | 180 | 0.8-1.0 |

### Example 3

TABLE 3
Experimental Parameters for Example 3.

| | | | | Flame + | |
|---|---|---|---|---|---|
| Heater | | | Traverse | ceramic | Flame + ceramic |
| SP | Voltage | Current | speed | resistance | electrical |
| (° C.) | (V) | (mA) | (mm/min) | (KΩ) | power (W) |
| 700 | 750 | 2.5 | 25-250 | 100-200 | 1.6 |
| Nozzle | Auxiliary | | | | |
| height | nozzle | Propane | | Powder | Plasma arc |
| H | height | flow | O₂ flow | size | diameter |
| (mm) | (mm) | (sccm) | (sccm) | (nm) | (mm) |
| 2.25 | N/A | 100 | 370 | 200 | .070-0.10 |

FIG. 3 shows images of actual test results from the experimental parameters and conditions shown in Table 3.

The shiny lines in FIG. 3a illustrate ceramic particles of 8% yttria-stabilized zirconia (“8YSZ”) that were sintered as the plasma within the flame as it traversed a path over the surface. The flame path is from the top of image to the bottom and then back up to the top, with this being repeated. Note the interrupted sintering pattern shown. Instead of a continuous sintering line, a series of discontinuous lines, angled (+/−) slightly off the flame direction occurred. These measure ˜0.9 mm in length, and include a separation distance of ˜0.2 mm Additionally, random sintering lines extend out from each side of the vertical path at a greater angle, and are also separated by a distance of ˜0.2 mm from the vertical sintered line segments. This pattern roughly simulates typical arrow fletching. Such patterns are more commonly formed at larger nozzle heights, which requires higher voltage, perhaps resulting in a high plasma energy, with multiple electrical plasma streams occurring with a somewhat repeatable, but irregular, fletching pattern. FIG. 3b shows a pattern of sintering lines at higher magnification all within one flame pass. The fully densified lines were each created in less than a second as the arc, in a very tight beam within the flame, jumps and then moves to create short sintered line segments as the flame moved across the powder coated surface. Depending on operating conditions and the coating, other patterns have been noted for the traverse of the arc. Some beams move back and forth along curves prior to moving to a new area to sinter, with one such added example as shown in FIG. 6e.

### Example 4

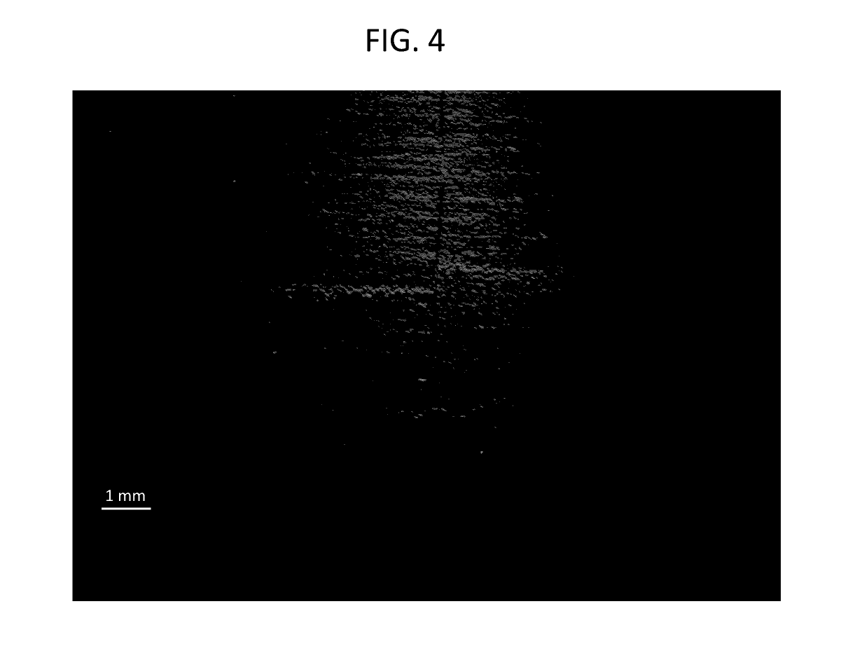

Example 4 illustrates the hardness of a processed FAFS coating. FIG. 4 shows a processed sample (alumina/YSZ composite #1 above) that was subjected to a stainless steel pick tip being dragged across the surface. The areas where the FAFS processing was executed actually abraded metal from the steel tip surface, such that metal residue was left behind. These are the gray lines in FIG. 4. X-ray analysis (EDX) confirmed these grey deposits to be material from the steel on similar samples.

### Experimental Parameters for Example 4.

| Heater | | | Traverse | Flame + | |
|---|---|---|---|---|---|
| SP | Voltage | Current | speed | ceramic | Flame + ceramic |
| (° C.) | (V) | (mA) | (mm/min) | resistance | electrical |
| N/A | 2000 | 14 | 50 | 43 | 8.4 |
| Nozzle | | | | | |
| height | Auxiliary | Propane | | Powder | Flame + plasma |
| H | nozzle | flow | O₂ flow | size | arc diameter |
| (mm) | height | (sccm) | (sccm) | (nm) | (mm) |
| 2.3 | 3.3 | 90 | 370 | 200 | 0.8-1.0 |

The results achieved differed widely from those achieved by flame or arc plasma alone. On both YSZ and LSM coatings, flame-only processing was performed and nominal or no sintering was achieved and the adhesion was very poor. A much higher current TIG welder was tried with the YSZ coating and the arc would jump from spot to spot where, it is believed, there was a lower electrical resistance to the powder coating. With the right conditions and lower current, TIG-treated material from a steady plasma arc should be scanned continuously over the surface to also achieve variable sintering. Also, any ionized gas stream used to propagate an electric arc could be used to create the features and microstructures of this invention.

The FAFS process uses a flame to define a path where the plasma arc is restricted and then the flame can be traversed or moved relatively over the area to be treated. Additionally, the flame has some conductivity and can support a lower resistance path, so that a lower power plasma arc can exist versus non-flame-based plasma arcs. The plasma is a composite of both a flame plasma and an electric arc plasma, which enables a lower current flow than is required to sustain a pure electric arc, so that the right amount of energy to properly sinter, without damaging the powder coating or substrate, can be achieved more readily. With appropriate equipment and setting, a non-flame ‘pure’ arc plasma could achieve selective sintering. Other energy sources, such as a laser, can be used to excite an initial plasma that can be used in place of the flame to control the location of the electric sintering beam or arc. The current and voltage required to form an arc plasma is known to vary with the composition of the gas medium. Another significant factor is pressure, and under reduced pressure, electric plasmas are more stable at lower current flows. Of course, any air that might be entrained should be included in the gas mix, so some form of enclosure or localized gas flow control would be necessary. The flame or heater helps to bring the coating material up to a temperature where electric current sintering can be effective.

The powder coating should be of good quality without coating material lacking in the area of processing. While the flame does control the zone of the electric plasma are, if there are holes or cracks in the coating, the arc can try to move to these areas of a lower resistance path and will jump over or move quickly by areas where the coating has significantly higher resistance.

Coating contaminants should be minimized, as is the case for most coating methods. Some contaminants might dramatically alter the melting point or resistance of the coating and result in different coating morphologies or properties as well as difficult to control currents or voltages. As with many processes, cleaner or more consistent properties are better. There could be benefits to some additional materials on processing, but uniformity is helpful in maintaining operating conditions.

Embodiments of the present invention include:
1. A method of manufacturing a coated area with variable amounts of sintering, the method comprising:
   a. providing a substrate having an exposed first surface,
   b. providing a powder having of a plurality of particles,
   c. disposing said powder to said first surface of said substrate to form a powder layer
   d. providing a gas capable of creating an electric plasma,
   e. providing an orifice capable of dispensing said plasma generating gas toward said powder layer on said substrate,
   f. creating a gas flow that connects a first electrode to the plasma generating gas so that a high voltage current can pass through the gas and powder layer to said substrate which is at a second electrical potential,
   g. electrically energizing said electrode causing a current flow through said gas and the powder layer,
   h. wherein said electrical potential enhances the powder sintering and creates a net electrical flow of at least 1 mA, and
   i. consolidating said powder on said substrate in said current flow area,
2. A device for sintering a powder coating on to a substrate comprising:
   a. at least one gas source capable of supplying a ionizing gas
   b. a gas delivery means, capable of delivering at least one gas to at least one electrode
   c. said electrode capable of producing an electric current sufficient through the gas to produce a plasma
   d. an electrical circuit configured to flow current through said plasma
   e. a controller or electrical circuit capable of controlling current or voltage
   f. a traversing means capable of traversing said electrode or moving said substrate while said plasma is energized with current.
3. A variable microstructure inorganic coated substrate or released film, comprising:
   a. a substrate having a powder on its surface.
   b. said powder on said substrate being in a state of variation in sintering over the scale of 30 microns or less.
4. The coating in 3. (above) wherein the substrate is an electrical conductor or a semiconductor, or composite containing a conductor or a semiconductor.
5. The coating in 3. (above) wherein the powder is a ceramic, metalloid, metal or semiconductor.
6. The coating in 3. (above) wherein the powder has an electrical conductivity less than that of said substrate.
7. The coating in 3. (above) wherein the microstructure changes occur with negligible composition variation.
8. The coating in 3. (above) wherein the microstructure changes occur over distances of less than 10 microns.
9. The coating in 3. (above) wherein the microstructure changes occur over distances of less than 3 microns.
10. The coating in 3. (above) wherein the microstructure change is a grain size change of at least 2 times.
11. The coating in 3. (above) wherein the microstructure change is a grain size change of at least 4 times.
12. The coating in 3. (above) wherein the microstructure change is a necking between particles width change of at least 2 times.
13. The coating in 3. (above) wherein the microstructure change is a necking between particles width change of at least 4 times.
14. The coating in 3. (above) wherein the microstructure is sufficient for the more sintered areas being stable while the less sintered areas can be removed by a removal process to which all areas are subjected.
15. The coating of 14. (above) wherein the removal process is a mechanical process such as brushing or being subjected to a fluid flow.
16. The method in 1. (above) where the gas is a flammable mixture and electrode that is adjacent to or in a flame.
17. The method in 16. (above) wherein said flame is in the temperature range of ˜1000° C. to ˜3000° C. and produces chemically and thermally generated ions as constituents of a plasma.
18. The method in 16. (above) wherein said flame produces chemically and thermally generated ions as constituents of a flame plasma and the electrical potential creates an arc-like plasma in the flame that raster's over the coating and produces small scale microstructure variations.
19. The method in 1. (above) wherein the gas flow over the surface is moved such that the area of current flow does not cover all the coating resulting in areas of more sintered material where the gas makes contract with the coating.
20. The method in 1. (above) wherein a plasma occurs at a voltage and current at least less than one-half of that possible without the ionizing gas in the ambient gas composition.
21. The method in 1. (above) wherein the electric arc is traversed over select areas where coating material is desired to remain for the product being made and subsequently the more sintered powder layer is removed when the substrate is subject to a cleaning or unsintered powder removal method.
22. The method in 1. (above) wherein the method is repeated at least twice over the substrate where the resulting coating is thicker or has layers of different composition.
23. The device of 2. (above) additionally comprising the gas source being a flammable gas fuel.
24. The device of 2. (above) additionally comprising a fuel delivery means such as a control valve, mass-flow controller or rotometer, capable of delivering at least one gaseous fuel to a torch
25. The device of 2. (above) additionally comprising a torch capable of producing a flame of sufficient temperature to produce chemically and thermally generated ions as constituents of a flame plasma.
26. The device of 2. (above) additionally comprising an electrical circuit configured to apply at least part of the range of ˜100 V to ˜5000 V of electrical potential and control a desired flow of current of ˜1 mA to ˜300 mA through said gas.
27. The device in 2. (above) wherein said traversing means is a robotic arm with multiple degrees of motion freedom so that the torch can be maintained near the same angle and distance to the substrate even when the substrate is a complex shape.
28. The device in 2. (above) further comprising a substrate heating system that brings the coating and substrate up to a desired initial temperature for processing.
29. The coating in 3. (above) wherein the microstructure changes occur over distances of less than 1 micron.

Unless indicated otherwise, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques.

While the invention has been particularly shown and described with reference to a preferred embodiment, it will be understood by those skilled in the art that various changes in form and detail may be made therein without departing from the spirit and scope of the invention.

All documents, books, manuals, papers, patents, published patent applications, guides, abstracts, and other references cited herein are incorporated by reference in their entirety. Other embodiments of the invention will be apparent to those skilled in the art from consideration of the specification and practice of the invention disclosed herein. It is intended that the specification and examples be considered as exemplary only, with the true scope and spirit of the invention being indicated by the following claims.

1. A method of manufacturing a coated area with variable amounts of sintering, the method comprising:
a) providing a substrate having an exposed first surface,
b) disposing powder onto said first surface of said substrate to form a powder layer
d) providing a gas capable of creating an electric plasma,
e) providing a conduit capable of dispensing said plasma generating gas toward said powder layer on said substrate,
f) creating a gas flow that closely enough connects a first electrode to the plasma generating gas so that a high voltage current can pass through the gas and powder layer to said substrate, which is at a second electrical potential,
g) electrically energizing said electrode causing a current flow through said gas and the powder layer,
h) wherein said electrical potential enhances the powder sintering and creates a net electrical flow of at least 1 mA, and
i) consolidating said powder on said substrate in said current flow area,

2. A device for sintering a powder coating on to a substrate comprising:
a) at least one gas source capable of supplying an ionizing gas
b) a gas delivery means, capable of delivering at least one gas to or close to at least one electrode
c) said electrode capable of producing an electric current sufficient through the gas to produce a plasma
d) an electrical circuit configured to flow current through said plasma and a powder to be sintered
e) a controller or electrical circuit capable of controlling current or voltage
f) a traversing means capable of traversing said electrode or moving said substrate while said plasma is energized with current so that a sintered pattern can be achieved.

3. A variable microstructure inorganic-coated substrate or released film, comprising:
a) a substrate having a powder on its surface,
b) said powder on said substrate being in a state of variation in sintering over the scale of 30 microns or less.

4. The coating in claim 3 wherein the substrate is an electrical conductor or a semiconductor, or a composite containing a conductor or a semiconductor.

5. The coating of claim 3 wherein the powder is a ceramic, metalloid, metal, or semiconductor.

6. The coating of claim 3 wherein the powder has an electrical conductivity less than that of said substrate.

7. The coating of claim 3 wherein the microstructure changes occur with negligible composition variation.

8. The coating of claim 3 wherein the microstructure changes occur over distances of less than 10 microns.

9. The coating of claim 3 wherein the microstructure changes occur over distances of less than 3 microns.

10. The coating of claim 3 wherein the microstructure change is a grain size change of at least 2 times.

11. The coating of claim 3 wherein the microstructure change is a grain size change of at least 4 times.

12. The coating of claim 3 wherein the microstructure change is a necking between particles width change of at least 2 times.

13. The coating of claim 3 wherein the microstructure change is a necking between particles width change of at least 4 times.

14. The coating of claim 3 wherein the microstructure is sufficient for the more sintered areas being stable while the less sintered areas can be removed by a removal process to which all areas are subjected.

15. The coating of claim 14 wherein the removal process is a mechanical process such as brushing or being subjected to a fluid flow or ultrasonic excited fluid.

16. The method in claim 1 where the said gas is a flammable mixture and electrode that is close to or in a flame.

17. The method of claim 16 wherein said flame is in the temperature range of 1000° C. to 3000° C. and produces chemically and thermally generated ions as constituents of a plasma.

18. The method of 16 wherein said flame produces chemically and thermally generated ions as constituents of a flame plasma and the electrical potential creates an arc-like plasma in the flame that rasters over the coating and produces small-scale microstructural variations.

19. The method of claim 1 wherein the gas flow over the surface is moved such that the area of current flow does not cover all the coating resulting in areas of more sintered material where the gas makes contract with the coating.

20. The method of claim 1 wherein a plasma occurs at a voltage and current at least less than one-half of that possible without the ionizing gas in the ambient gas composition.

21. The method of claim 1 wherein the electric arc is traversed over select areas where coating material is desired to remain for the product being made and subsequently the more sintered powder layer is removed when the substrate is subject to a cleaning or unsintered powder removal method.

22. The method of claim 1 wherein the method is repeated at least twice over the substrate where the resulting coating is thicker or has layers of different composition.

23. The device of claim 2 additionally comprising the gas source being a flammable gas fuel.

24. The device of claim 2 additionally comprising a fuel delivery means, such as a control valve, mass-flow controller or rotometer, capable of delivering at least one gaseous fuel to a torch.

25. The device of claim 2 additionally comprising a torch capable of producing a flame of sufficient temperature to produce chemically and thermally generated ions as constituents of a flame plasma.

26. The device of claim 2 additionally comprising an electrical circuit configured to apply at least part of the range of 100 V to 5000 V of electrical potential and control a desired flow of current of 2 mA to 300 mA through said gas.

27. The device of claim 2 wherein said traversing means is a robotic arm with multiple degrees of motion freedom so that the torch can be maintained near the same angle and distance to the substrate even when the substrate is a complex shape.

28. The device of claim 2 further comprising a substrate temperature controlling system that brings the coating and substrate to a desired temperature for processing.
